(19) United States
(12) Patent Application Publication
(10) Pub. No.: US 2007/0037364 A1
(43) Pub. Date: Feb. 15, 2007

(54) Method for manufacturing semiconductor chip

(76) Inventors: Daihei Sugita, Saitama (JP); Masateru Fukuoka, Osaka (JP); Munehiro Hatai, Osaka (JP); Satoshi Hayashi, Osaka (JP); Kazuhiro Shimomura, Saitama (JP); Yoshikazu Kitajima, Saitama (JP); Yasuhiko Oyama, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/577,442

(22) PCT Filed: Dec. 2, 2004
(86) PCT No.: PCT/JP04/17955

§ 371 Date: Jul. 13, 2006

(30) Foreign Application Priority Data
Dec. 12, 2003 (JP) 2003-403431
Mar. 31, 2004 (JP) 2004-107584
Sep. 28, 2004 (JP) 2004-282807
Sep. 28, 2004 (JP) 2004-282808

(51) Int. Cl. H01L 21/00

(52) U.S. Cl. 438/464

(57) ABSTRACT

It is the object of the invention to provide a method for manufacturing a semiconductor chip capable of obtaining a semiconductor chip at a high manufacturing efficiency without damages. The invention is a method for manufacturing a semiconductor chip, which comprises a tape adhesion step of sticking a pressure sensitive adhesive tape for dicing having a pressure sensitive adhesive layer containing a gas generating agent for generating a gas by radiating light to a semiconductor wafer with a circuit formed; a dicing step for dicing the wafer with the pressure sensitive adhesive tape for dicing stuck and dividing the semiconductor wafer into each semiconductor chip; a separation step of separating at least a portion of the pressure sensitive adhesive tape for dicing from the semiconductor chip by radiating light to the divided each semiconductor chip; and a pickup step of picking the semiconductor chip up by a needle-less pickup method.

### TECHNICAL FIELD

The invention relates to a method for manufacturing a semiconductor chip capable of obtaining a semiconductor chip at a high manufacturing efficiency without damages.

### BACKGROUND ART

A semiconductor chip such as IC and LSI has generally been manufactured by obtaining a semiconductor wafer by slicing a rod type high purity semiconductor single crystal and the like, forming a prescribed circuit pattern in the surface of the semiconductor wafer by using photoresist, successively grinding the rear face of the semiconductor wafer by a grinding machine for making the semiconductor wafer as thin as 100 to 300 μm, and finally dicing the semiconductor wafer into a chip.

Conventionally, at the time of dicing, a method involving the following steps has been employed: that is, at first sticking a pressure sensitive adhesive tape for dicing to the rear face side of a semiconductor wafer, next dicing the semiconductor wafer vertically and transversely while it being stuck and fixed to divide it into respective semiconductor chips, and after that, picking up each of the formed semiconductor chips by pushing it up by a needle from the dicing tape side, and fixing each chip on a die pad. For example, Patent Document 1 discloses a grinding processing method of a semiconductor wafer using a grinding processing machine having a plurality of wheel spindles for simultaneously carrying out processings of grinding a semiconductor wafer thin from the rear face side by at least one wheel spindle and cutting and dividing the semiconductor wafer into rectangular shape by at least one of other wheel spindles and even in such a method, a pressure sensitive adhesive tape for dicing is employed for preventing the positioning difference and the like of the semiconductor wafer.

At the time of dicing, to reliably prevent the positioning difference and the like of the semiconductor wafer, the pressure sensitive adhesive tape for dicing for fixing the semiconductor wafer is required to have a high adhesion. However, if the adhesion of the pressure sensitive adhesive tape for dicing is set to be high, it becomes difficult to separate the obtained semiconductor chips from the pressure sensitive adhesive tape for dicing and there occurs a problem that semiconductor wafer is sometimes damaged at the time of picking up the semiconductor chips by pushing them with a needle and the like.

To deal with the problem, a method of using a curable type pressure sensitive adhesive as the pressure sensitive adhesive of the pressure sensitive adhesive tape for dicing has been employed. The method can be used for separating the obtained semiconductor chips from the pressure sensitive adhesive tape for dicing after the adhesion is lowered by curing the pressure sensitive adhesive even in the case of fixing a semiconductor wafer with a relatively high adhesion and dicing the semiconductor wafer. However, even if the curable type pressure sensitive adhesive is used, the adhesion is changed only in a narrow range and therefore, in the case the provided adhesion is so high as to sufficiently prevent the positioning difference and the like of the semiconductor wafer at the time of dicing, the adhesion is not so much decreased even after curing and it is therefore still difficult to pick up the semiconductor chips without damaging them at the time of pushing them with a needle and the like.

Further, in the case the circuit pattern formed in the surface of a semiconductor wafer is extremely fine or susceptive to damages, the circuit pattern has sometimes been damaged by hitting with a wheel stone at the time of dicing or by a cutting powder generated by the dicing. In such a case, a wafer backside dicing method of sticking the pressure sensitive adhesive tape for dicing to the surface side of the semiconductor wafer and dicing the semiconductor wafer from the rear face side has been carried out. However, at the time of picking up the semiconductor wafer obtained by the wafer backside dicing method, the surface side of the semiconductor wafer, that is the side where the circuit pattern is formed is to be pushed up by a needle and the like and therefore, there is a problem that the circuit pattern may be damaged in this case.

Further, in these years, in terms of the requirement of cost down and the like, it has been required to manufacture semiconductor chips at a high productivity and the utmost efficiency has been required for the respective steps. Particularly, the step of picking up the semiconductor chips by pushing them up with a needle and the like after dicing increases the number of damaged semiconductor chips if the pickup speed is increased and thus considerably affects the yield and this step is one of problems for productivity improvement.

Patent Document 1: Japanese Kokai Publication Hei-7-78793

### DISCLOSURE OF THE INVENTION

### Problems which the Invention is to solve

In view of the above-mentioned state of the art, the invention aims to provide a method for manufacturing a semiconductor chip capable of obtaining semiconductor chips at a high productivity without damages.

### Means for Solving the Object

The invention is a method for manufacturing a semiconductor chip, which comprises a tape adhesion step of sticking a pressure sensitive adhesive tape for dicing having a pressure sensitive adhesive layer containing a gas generating agent for generating a gas by radiating light to a semiconductor wafer with a circuit formed; a dicing step for dicing the wafer with the pressure sensitive adhesive tape for dicing stuck and dividing the semiconductor wafer into each semiconductor chip; a separation step of separating at least a portion of the pressure sensitive adhesive tape for dicing from the semiconductor chip by radiating light to the divided each semiconductor chip; and a pickup step of picking the semiconductor chip up by a needle-less pickup method.

Hereinafter the invention will be described more in detail.

A method for manufacturing a semiconductor chip of the invention comprises a tape adhesion step of sticking a pressure sensitive adhesive tape for dicing having a pressure sensitive adhesive layer containing a gas generating agent for generating a gas by radiating light to a semiconductor wafer having a circuit therein. Sticking such a pressure sensitive adhesive tape for dicing makes it possible to prevent positioning difference and the like of the semiconductor wafer in the dicing step, which will be described later, and at the same time makes it possible to pick up semiconductor chips by a needle-less pickup method which does not damage the semiconductor chips unlike a conventional needle pickup method.

The semiconductor wafer having a circuit therein may be those which are manufactured by conventionally known methods and may include those obtained by forming a circuit pattern on the surface of the obtained wafer obtained by slicing a semiconductor single crystal and the like by using photoresist, and then grinding it to a prescribed thickness.

The semiconductor wafer is not particularly limited in the thickness and may have a thickness of 100 to 300 μm as conventional ones and also 50 μm or thinner. The method for manufacturing the semiconductor chip of the invention is particularly suitable for manufacturing semiconductor chips from a semiconductor wafer with a thickness of 50 μm or thinner at a high productivity.

The above-mentioned pressure sensitive adhesive tape for dicing has a pressure sensitive adhesive layer containing a gas generating agent for generating a gas by radiating light. Since such a pressure sensitive adhesive layer exists, even if sufficiently high adhesion to prevent positioning difference and the like of the semiconductor wafer in the dicing step, a gas generated from the gas generating agent is released in the interface between the pressure sensitive adhesive layer and the semiconductor wafer by radiating light at the time of separation to separate at least a portion of the adhesive face and lower the adhesive strength and accordingly, the pressure sensitive adhesive tape can easily be separated from the semiconductor wafer and the semiconductor chips can be picked up by a needle-less pickup method without damaging the semiconductor chips.

The gas generating agent for generating a gas by light radiation is not particularly limited and, for example, azo compounds and azide compounds may be used preferably.

Examples of the azo compounds are 2,2′-azobis(N-cyclohexyl-2-methylpropionamide), 2,2′-azobis[N-(2-methylpropyl)-2-methylpropionamide], 2,2′-azobis(N-butyl-2-methylpropionamide), 2,2′-azobis[N-(2-methylethyl)-2-methylpropionamide], 2,2′-azobis(N-hexyl-2-methylpropionamide), 2,2′-azobis(N-propyl-2-methylpropionamide), 2,2′-azobis(N-ethyl-2-methylpropionamide), 2,2-azobis{2-methyl-N-[1,1-bis(hydroxymethyl)-2-hydroxyethyl]propionamide}, 2,2′-azobis{2-methyl-N-[2-(1-hydroxybutyl)]propionamide}, 2,2′-azobis[2-methyl-N-(2-hydroxyethyl)propionamide], 2,2′-azobis[N-(2-propenyl)-2-methylpropionamide], 2,2′-azobis[2-(5-methyl-2-imidazolin-2-yl)propane]dihydrochloride, 2,2′-azobis[2-(2-imidazolin-2-yl)propane]dihydrochloride, 2,2′-azobis[2-(2-imidazolin-2-yl)propane]disulfate dihydrate, 2,2′-azobis[2-(3,4,5,6-tetrahydropyrimidin-2-yl)propane]dihydrochloride, 2,2′-azobis{2-[1-(2-hydroxyethyl)-2-imidazolin-2-yl]propane}dihydrochloride, 2,2′-azobis[2-(2-imidazolin-2-yl)propane], 2,2′-azobis(2-methylpropionamidine)hydrochloride, 2,2′-azobis(2-aminopropane)dihydrochloride, 2,2′-azobis[N-2-carboxyacyl)-2-methyl-propionamidine], 2,2′-azobis(2-{N-(2-carboxyethyl)amidine]propane}, 2,2′-azobis (2-methylpropionamidoxime), dimethyl 2,2′-azobis(2-methylpropionate), dimethyl 2,2′-azobisisobutylate, 4,4′-azobis(4-cyanocarbonic acid), 4,4′-azobis(4-cyanopentanoic acid), 2,2′-azobis(2,4,4-trimethylpentane), and the like.

These azo compounds generate nitrogen gas by radiating light, particularly ultraviolet rays with wavelength of about 365 nm.

The above-mentioned azo compounds are preferable to have a 10-hour half life temperature of 80° C. or higher. If the 10-hour half life temperature is lower than 80° C., the pressure sensitive adhesive tape of the invention may possibly generate foams at the time of forming and drying the pressure sensitive adhesive layer by casting, or cause decomposition reaction with the lapse of time and thus cause bleeding out of the decomposition residues, or generate a gas with the lapse of time and are partially separated in the interface of the pressure sensitive adhesive layer and the adherend stuck thereto. If the 10-hour half life temperature is 80° C. or higher, heat resistance is high and the pressure sensitive adhesive tape can be used at a high temperature and stored stably.

The above-mentioned azo compounds having a 10-hour half life temperature of 80° C. or higher may be azoamide compounds represented by the following general formula (1). The azo compounds represented by the general formula (1) are excellent in heat resistance and also in solubility in polymers having a pressure sensitive adhesive property such as acrylic acid alkyl ester polymers, which will be described later and are adjusted not to exist in form of particles in the pressure sensitive adhesive layer.
(Chem. 1] 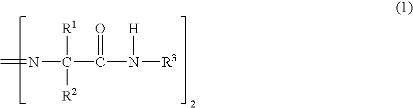
in the formula (1), R¹ and R² independently represent a lower alkyl group; R³ represents a saturated alkyl group having 2 or more carbon atoms. And R¹ and R² may be same or different.

Examples of the azoamide compounds represented by the above-mentioned general formula (1) are 2,2′-azobis(N-cyclohexyl-2-methylpropionamide), 2,2′-azobis[N-(2-methylpropyl)-2-methylpropionamide], 2,2′-azobis(N-butyl-2-methylpropionamide), 2,2′-azobis[N-(2-methylethyl)-2-methylpropionamide], 2,2′-azobis(N-hexyl-2-methylpropionamide), 2,2′-azobis(N-propyl-2-methylpropionamide), 2,2′-azobis(N-ethyl-2-methylpropionamide), 2,2′-azobis{2-methyl-N-[1,1-bis(hydroxymethyl)-2-hydroxyethyl]propionamide}, 2,2′-azobis{2-methyl-N-[2-(1-hydroxybutyl)]propionamide}, 2,2′-azobis[2-methyl-N-(2-hydroxyethyl)]propionamide], 2,2′-azobis[N-(2-propenyl)-2-methylpropionamide], and the like. Among them, 2,2′-azobis(N-butyl-2-methylpropionamide) and 2,2′-azobis[N-(2-propenyl)-2-methylpropionamide] are excellent in the solubility in solvents and therefore preferable to be used.

As the above-mentioned azide compounds, azido group-containing polymers such as 3-azidomethyl-3-methyloxetane, terephthal azide, p-tert-butylbenzazide, glycidyl azide polymers obtained by ring opening polymerization of 3-azidomethyl-3-methyloxetane. These azide compounds generate nitrogen gas by radiating light, particularly ultraviolet rays with wavelength of about 365 nm.

Among these gas generating agents, the above-mentioned azide compounds have a problem that they are difficult to be handled since they are easily decomposed by applying impact and release nitrogen gas. Further, once they begin to be decomposed, the above-mentioned azide compounds cause chain reaction and explosively release nitrogen gas and it becomes uncontrollable, so that the adherend might be damaged by the explosively generated nitrogen gas. Because of these problems, the use amount of the above-mentioned azide compounds is limited, however if the amount is limited, a sufficient effect cannot be obtained in some cases.

On the other hand, the above-mentioned azo compounds are very easy to be handled since unlike the azide compounds, they do not generate a gas by the impact. Further, they do not cause chain reaction and do not release a gas explosively and damage the adherend and they stop gas generation if the light radiation is stopped, and therefore, these azo compounds are advantageously controllable in the adhesive property in accordance with the purpose. Accordingly, the azo compounds are more preferable to be used as the above-mentioned gas generating agent.

The above-mentioned gas generating agent is preferable to be dissolved in the pressure sensitive adhesive layer. If the gas generating agent is dissolved in the pressure sensitive adhesive layer, the gas generated from the gas generating agent can efficiently be released out of the pressure sensitive adhesive layer when light is radiated. If the gas generating agent exists in form of particles in the pressure sensitive adhesive layer, the locally generated gas may possibly generate bubbles in the pressure sensitive adhesive layer and may hardly be released out of the pressure sensitive adhesive layer. Further, when light is radiated for stimulation for generating the gas, the light may possibly be scattered in the interfaces of the particles to decrease the gas generation efficiency or the surface smoothness of the pressure sensitive adhesive layer is worsened. In this connection, that the gas generating agent is dissolved in the pressure sensitive adhesive layer can be confirmed if no particle of the gas generating agent is observed when the pressure sensitive adhesive layer is observed by an electron microscope.

To dissolve the gas generating agent in the pressure sensitive adhesive layer, a gas generating agent soluble in the pressure sensitive adhesive composing the above-mentioned pressure sensitive adhesive layer may be selected. In the case a gas generating agent which is not dissolved in the pressure sensitive adhesive is selected, it is preferable to disperse the gas generating agent in the pressure sensitive adhesive layer as finely as possible by using a dispersion apparatus or by using a dispersant in combination. To finely disperse the gas generating agent in the pressure sensitive adhesive layer, the gas generating agent is preferable to be very small particles and further preferable to be smaller particles by, for example, a dispersion apparatus, a mixing kneader and the like based on the necessity. That is, it is preferable that the gas generating agent is dispersed to the extent that the gas generating agent cannot be observed when the above-mentioned pressure sensitive adhesive layer is observed by an electron microscope.

In the pressure sensitive adhesive tape for dicing, the gas generated from the above-mentioned gas generating agent is preferable to be released out of the pressure sensitive adhesive layer. Accordingly, the gas generated from the gas generating agent by radiating light to the adhesive face of the pressure sensitive adhesive tape for dicing stuck to the semiconductor chips separates at least a portion of the adhesive face of the semiconductor chips and lowers the adhesive strength to make the separation easy. At that time, most of the gas generated from the gas generating agent is preferable to be released out of the pressure sensitive adhesive layer. If most of the gas generated from the gas generating agent is not released out of the pressure sensitive adhesive layer, bubbles are generated in the entire part of the pressure sensitive adhesive layer owing to the gas generated from the gas generating agent and no sufficient effect to lower the adhesive strength can be obtained and the adhesive deposit may possibly be left on the semiconductor chips. In this connection, a portion of the gas generated from the gas generating agent is allowed to be dissolved in the pressure sensitive adhesive layer or exist in form of bubbles in the pressure sensitive adhesive layer to the extent that the gas does not leave the adhesive deposit on the semiconductor chips.

The pressure sensitive adhesive comprising the above-mentioned pressure sensitive adhesive layer is preferable to be crosslinked by stimulation and increase the elastic modulus. If such a pressure sensitive adhesive is used, the adhesion can be lowered and separation is made easier by increasing the elastic modulus by stimulation at the time of separation. Further, at the time of separation, if crosslinking is carried out prior to the gas generation, the elastic modulus of the entire body of the pressure sensitive adhesive layer is increased and if the gas is generated from the gas generating agent in the cured substance whose elastic modulus is increased, most of the generated gas is released and the released gas separates at least a portion of the adhesive face of the pressure sensitive adhesive layer from the semiconductor chips and lower the adhesive strength.

The stimulation for crosslinking the pressure sensitive adhesive may be same as or different from the stimulation for generating the gas from the gas generating agent. In the case these stimulations are different, at the time of separation, the stimulation for crosslinking a crosslinkable component is applied before the stimulation for generating the gas from the gas generating agent is applied.

As such a pressure sensitive adhesive, a pressure sensitive adhesive which comprises a photocurable type pressure sensitive adhesive obtained by containing, as main components, a polymerizable polymer of acrylic acid alkyl ester type and/or methacrylic acid alkyl ester type having a radical polymerizable unsaturated bond in a molecule and a radical polymerizable polyfunctional oligomer or monomer and, if necessary, a photopolymerization initiator and a thermosetting type pressure sensitive adhesive obtained by containing, as main components, a polymerizable polymer of acrylic acid alkyl ester type and/or methacrylic acid alkyl ester type having a radical polymerizable unsaturated bond in a molecule and a radical polymerizable polyfunctional oligomer or monomer and, a heat polymerization initiator, can be used.

The pressure sensitive adhesive layer comprising a post-curing type adhesive such as a photocurable type pressure sensitive adhesive or a thermosetting type pressure sensitive adhesive is evenly and quickly crosslinked and polymerized in the entire body by radiating light or heating and is unified, so that the elastic modulus is considerably increased and the adhesion is greatly decreased owing to the polymerization curing. Also, when a gas is generated from the gas generating agent in the hard cured substance having the improved elastic modulus, most of the generated gas is released outside, and the released gas separates at least a portion of the adhesive face of the pressure sensitive adhesive from the semiconductor chips and lowers the adhesive strength.

The above-mentioned polymerizable polymer can be obtained by previously synthesizing (meth)acrylic type polymer having a functional group in a molecule (hereinafter, referred to as functional group-containing (meth)acrylic type polymer) and causing reaction of the polymer with a compound having a functional group reactive on the functional group of the above-mentioned polymer and a radical polymerizable unsaturated bond in a molecule (hereinafter, referred to as functional group-containing unsaturated compound).

Similar to a common (meth)acrylic type polymer as a polymer having a pressure sensitive adhesive property at a normal temperature, the above-mentioned functional group-containing (meth)acrylic type polymer can be obtained by copolymerizing an acrylic acid alkyl ester and/or a methacrylic acid alkyl ester in which an alkyl group has carbon atoms generally in the range from 2 to 18 as a main monomer and the functional group-containing monomers and further other monomers for modification copolymerizable with these monomers, if necessary, by a conventional method. The weight average molecular weight of the above-mentioned functional group-containing (meth)acrylic type polymer is generally about 200,000 to 2,000,000.

Examples of the above-mentioned functional group-containing monomer are carboxyl group-containing monomers such as acrylic acid and methacrylic acid; hydroxyl group-containing monomers such as hydroxyethyl acrylate and hydroxyethyl methacrylate; epoxy group-containing monomers such as glycidyl acrylate and glycidyl methacrylate; isocyanate group-containing monomers such as isocyanatoethyl acrylate and isocyanatoethyl methacrylate; and amino group-containing monomers such as aminoethyl acrylate and aminoethyl methacrylate.

Examples of the above-mentioned copolymerizable other monomers for modification may include various kinds of monomers to be used for the common (meth)acrylic type polymers such as vinyl acetate, acrylonitrile, and styrene.

As the functional group-containing unsaturated compound to be reacted with the above-mentioned functional group-containing (meth)acrylic type polymer, monomers same as the above exemplified functional group-containing monomers in accordance with the functional group of the functional group-containing (meth)acrylic type polymer can be used. For example, in the case the functional group of the functional group-containing (meth)acrylic type polymer is a carboxyl group, epoxy group-containing monomers and isocyanate group-containing monomers may be used; in the case the functional group is a hydroxyl group, isocyanate group-containing monomers may be used; in the case the functional group is an epoxy group, carboxyl group-containing monomers and amide group-containing monomers such as acrylamide may be used; and in the case the functional group is an amino group, epoxy group-containing monomers may be used.

As the above-mentioned polyfunctional oligomer or monomer, those having a molecular weight of 10,000 or lower are preferable and those having a molecular weight of 5,000 or lower and 2 to 20 radical polymerizable unsaturated bonds in a molecule are more preferable so as to efficiently form three-dimensional nets in the pressure sensitive adhesive layer by heating or radiating light. Examples of such preferable polyfunctional oligomer or monomer are trimethylolpropane triacrylate, tetramethylolmethane tetraacrylate, pentaerythritol triacrylate, pentaerythritol tetraacrylate, dipentaerythritol monohydroxypentaacrylate, dipentaerythritol hexaacrylate, and methacrylates of the above exemplified compounds. Additionally, 1,4-butylene glycol diacrylate, 1,6-hexanediol diacrylate, polyethylene glycol diacrylate, commercialized oligoester acrylates and methacrylates of the above exemplified compounds can be exemplified. These polyfunctional oligomers or monomers may be used alone or two or more of them may be used in combination.

As the above-mentioned photopolymerization initiator, those which are activated by radiating light having wavelength of 250 to 800 nm can be exemplified and examples of such photopolymerization initiators are photoradical polymerization initiators, e.g. acetophenone derivative compounds such as methoxyacetophenone; benzoin ether type compounds such as benzoin propyl ether and benzoin isobutyl ether; ketal derivative compounds such as benzyl dimethyl ketal and acetophenone diethyl ketal; phosphine oxide derivative compounds; bis(η5-cyclopentadienyl)titanocene derivative compounds, benzophenone, Michler's ketone, chlorothioxanthone, dodecylthioxanthone, dimethylthioxanthone, diethylthioxanthone, α-hydroxycyclohexyl phenyl ketone, and 2-hydroxymethylphenylpropane. These photopolymerization initiators may be used alone or two or more of them may be used in combination.

In the case the above-mentioned photopolymerization initiator is used, it is preferable to add 2 phr or more to prevent the curing inhibition of the above-mentioned post-curing type pressure sensitive adhesive.

As the above-mentioned heat polymerization initiator, those which are decomposed by heat and generate active radicals for starting the polymerization curing can be exemplified and preferable examples are dicumyl peroxide, di-t-butyl peroxide, t-butyl peroxybenzoate, t-butyl hydroperoxide, benzoyl peroxide, cumene hydroperoxide, diisopropylbenzene hydroperoxide, paramenthane hydroperoxide, and di-t-butyl peroxide. Among them, because of high heat decomposition temperature, cumene hydroperoxide, paramenthane hydroperoxide, and di-t-butyl peroxide are preferable. Those which are commercialized among these heat polymerization initiators are not particularly limited and PERBUTYL D, PERBUTYL H, PERBUTYL P, and PERMENTA H (all manufactured by NOF CORPORATION) are preferable. These heat polymerization initiators may be used alone or two or more of them may be used in combination.

Besides the above-mentioned components, the above-mentioned post-curing type pressure sensitive adhesive may properly contain various kinds of polyfunctional compounds to be added to common pressure sensitive adhesives such as isocyanate compounds, melamine compounds, and epoxy compounds based on the necessity to adjust the cohesion as the pressure sensitive adhesive. Further, conventionally known additives such as a plasticizer, a resin, a surfactant, a wax, and a finely granular filler may also be added.

The above-mentioned pressure sensitive adhesive may be subjected to the antistatic treatment. If the pressure sensitive adhesive tape for dicing is charged with static electricity, it becomes impossible to pick up self separated semiconductor chips as described later or an adverse effect on the manufacturing of the semiconductor chips by attraction of airborne fine particles and the like may possibly be caused. A method for carrying out the antistatic treatment of the pressure sensitive adhesive is not particularly limited and for example, addition of ionic surfactants and metal fine particles to the pressure sensitive adhesive can be exemplified. Particularly, addition of metal fine particles and polymer type ionic surfactants is preferable since it does not cause any adverse effect on the adhesion.

Before light radiation, the lower limit of the adhesion of the above-mentioned pressure sensitive adhesive layer to the semiconductor wafer is preferable to be 0.5 N/25 mm and the upper limit of that is preferable to be 10 N/25 mm. If it is lower than 0.5 N/25 mm, the adhesion is so insufficient as to allow the semiconductor wafer to move during the dicing and if it is more than 10 N/25 mm, the adhesion may not be decreased so sufficiently to make the pickup possible even by radiating light.

The lower limit of the shear modulus of the above-mentioned pressure sensitive adhesive layer at 23° C. before radiating light is preferable to be 5×10⁴ Pa. If it is lower than 5×10⁴ Pa, the semiconductor wafer may not be diced precisely in some cases.

The thickness of the pressure sensitive adhesive layer is not particularly limited and the lower limit of that is preferably 3 μm and the upper limit of that is preferably 50 μm. If it is thinner than 3 μm, the adhesive strength is sometimes so insufficient that some chips may be passed over at the time of dicing and if it is more than 50 μm, the adhesive strength is so high as to deteriorate the separation property and make desirable separation impossible in some cases.

The pressure sensitive adhesive tape for dicing is preferable to be a one-side coated pressure sensitive adhesive tape with the pressure sensitive adhesive layer formed only in one side of a substrate.

The above-mentioned substrate is not particularly limited if the substrate transmits light or light passes through the substrate and examples are sheets of transparent resins such as acrylic polymers, polyolefins, polycarbonates, vinyl chlorides, ABS, polyethylene terephthalate (PET), nylon, polyurethanes, and polyimides, sheets having mesh structure, and perforated sheets.

The above-mentioned substrate may be selective in accordance with the separation step and the pickup step, which will be described later.

For example, in the case the pressure sensitive adhesive tape for dicing is expanded in the pickup step described later, the substrate is preferable to have a flexible layer having a 20% elongation load of 25 N/25 mm or lower in the case the film thickness is 100 μm. If the substrate has such a flexible layer, the pressure sensitive adhesive tape for dicing may easily be expanded. If the 20% elongation load of the flexible layer is more than 25 N/25 mm, it is required to apply strong tensile force for expansion of the pressure sensitive adhesive tape for dicing and therefore large scale apparatus is required or the tensile force becomes uneven to cause positioning difference of the semiconductor chips.

In the case the substrate has the above-mentioned flexible layer, to further improve the self-separation property by light radiation, the substrate may further have a highly rigid layer between the pressure sensitive adhesive layer and the flexible layer. The highly rigid layer is preferable to have a 20% elongation load of 100 N/25 mm or higher in the case the film thickness is 100 μm. The upper limit of the 20% elongation load of the highly rigid layer is not particularly limited, however it is required to proper to be cut by a dicing saw. Therefore, the lower limit of the thickness of the highly rigid layer is preferably 5 μm and the upper limit of that is preferably 30 μm.

The same effect can be obtained by installing a reinforcing plate having a high rigidity in the face on the opposite to the pressure sensitive adhesive side for supporting the above-mentioned flexible layer. The reinforcing plate is not particularly limited if it can transmit light or light can pass through it and examples of the plate are glass plates, acrylic plates, and PET plates. The supporting plate necessarily contacts with the flexible layer and it is not necessarily required for the plate to be stuck to layer.

Further, in the case the semiconductor chips are self-separated by radiating high intense ultraviolet rays in the separation step described later, it is no need to expand the pressure sensitive adhesive tape for dicing in the pickup step, and therefore a substrate having rigidity sufficient to work as the reinforcing plate for preventing the deformation of the wafer may be used as the above-mentioned substrate. As such a substrate, those having a 20% elongation load of 100 N/25 mm or higher in the case of the film thickness of 100 μm are preferable, since the self-separation property is improved. Use of a substrate having such a high rigidity makes it possible to support the semiconductor wafer and prevent it from damages in the case the semiconductor wafer having a thickness of 50 μm or thinner is handled.

The substrate is preferable to be subjected to antistatic treatment. If the substrate is charged by static electricity and the like, as it will be described later, the self-separated semiconductor chips cannot be picked up or airborne particles and the like may be attracted to the semiconductor chips and thus adverse effects are caused in the manufacturing of the semiconductor chip. A method for carrying out the antistatic treatment is not particularly limited and for example, there are methods of adding an antistatic agent to the substrate and applying an antistatic agent to the substrate surface. The antistatic agent is not particularly limited and for example, transparent conductive plasticizers, surfactants, and metal fine particles can be exemplified.

The thickness of the substrate is not particularly limited and the lower limit is preferably 30 μm and the upper limit is preferably 200 μm. If it is thinner than 30 μm, the independency of the pressure sensitive adhesive tape for dicing is so insufficient as to make its handling difficult in some cases and if it is more than 200 μm, a trouble may be caused at the time of separating the pressure sensitive adhesive tape for dicing.

A method for manufacturing the pressure sensitive adhesive tape for dicing is not particularly limited and for example, a method of applying a pressure sensitive adhesive and the like containing the above-mentioned gas generating agent to the surface of the above-mentioned substrate by a doctor knife, a spin coater and the like can be exemplified.

In the tape adhesion step, sticking the pressure sensitive adhesive tape to the face of the semiconductor wafer having a circuit where no circuit is formed is generally carried out. However, in the case the formed circuit is particularly susceptive to damages, the pressure sensitive adhesive tape may be stuck to the face where the circuit is formed in terms of the surface protection at the time of dicing. In this case, so-called wafer backside dicing is to be carried out and in the method for manufacturing semiconductor chip of the invention, since the semiconductor chips are to be picked up by a needle-less pickup method as described later, the circuit is not damaged at the time of pickup unlike the case of a conventional method.

The method for manufacturing the semiconductor chip of the invention comprises a dicing step of dicing the wafer with the pressure sensitive adhesive tape for dicing stuck and dividing the wafer into each semiconductor chip.

A dicing method is not particularly limited and for example, a conventionally known method of cutting and dividing the wafer using a wheel stone may be employed.

The method for manufacturing the semiconductor chip of the invention comprises a separation step of separating at least a portion of the pressure sensitive adhesive tape for dicing from the semiconductor chips by radiating light to the pressure sensitive adhesive tape for dicing stuck to the divided each semiconductor chip.

Since the pressure sensitive adhesive tape for dicing contained the gas generating agent as described above, a gas generated by radiating light is released to the interface of the pressure sensitive adhesive layer and the semiconductor chips to separate at least a portion of the adhesive face and lower the adhesive strength and therefore the semiconductor chips are easily separated.

The inventors of the invention have made various investigations and consequently have found that the semiconductor chips can easily be picked up by the needle-less pickup method using no needle in the pickup step, which will be described later, by properly controlling a light radiation method in the above-mentioned separation step and that damages or cracks of the semiconductor chips due to the impact at the time of pickup can be prevented and accordingly have accomplished the invention.

That is, in the separation step, the pickup by the needle-less pickup method can be well carried out by either radiating light having radiation intensity of 500 mW/cm² or higher at wavelength of 365 nm in the above-mentioned separation step or radiating light immediately before the semiconductor chips are aspirated by an aspiration means or while the semiconductor chip is aspirated by an aspiration means.

In this description, the needle-less pickup method means a method other than the method of picking up the semiconductor chips by pushing up them with a needle and may include an adsorption means by an aspiration means such as an aspiration pad or an adsorption tool with a liquid such as water stuck, means of pinching and picking up chips by forceps having a buffering mechanism, and the like.

In the case ultraviolet rays having a radiation intensity of 500 mW/cm² or higher at wavelength of 365 nm are radiated, since a large quantity of the gas is generated within a short time, the semiconductor chips can spontaneously be separated from the pressure sensitive adhesive layer and the separated semiconductor chips are thus kept as if they float on the pressure sensitive adhesive layer (hereinafter, it is referred to as self separation). In the case of such self separation, it is made possible to pick up the semiconductor chips easily by the needle-less pickup method using no needle and accordingly, the semiconductor chips are prevented from damages due to the impacts at the time of pickup or occurrence of cracks can be prevented. In the case ultraviolet rays having a radiation intensity of 1,000 mW/cm² or higher at wavelength of 365 nm are radiated, self separation can be carried out more reliably and therefore it is preferable. The upper limit of the radiation intensity of ultraviolet rays is preferably 10,000 mW/cm² at wavelength of 365 nm. If it is more than 10,000 mW/cm², the cost for a radiation apparatus is remarkably increased and it is not practical. In consideration of the cost, it is supposed that the upper limit of that is actually about 5,000 mW/cm² in an actual production field.

The ultraviolet rays of the intensity may be radiated from a common light source such as an ultraviolet lamp, however in general, it is difficult to actualize such high intensity. In that case, the ultraviolet rays radiated from a light source are converged to obtain the high intensity ultraviolet rays. The method for converging the light may be methods carried out using light converging mirrors or light converging lenses.

In the case strong ultraviolet rays are radiated for a prescribed prior or longer, even if pickup by the needle-less pickup method is applicable, the oily decomposition product derived from components contained in the pressure sensitive adhesive layer of the pressure sensitive adhesive tape for dicing is generated and the oily decomposition product may possibly pollute the semiconductor chips.

Therefore, the inventors of the invention have made various investigations and accordingly have found that the semiconductor chips can easily and reliably be picked up by the needle-less pickup method using no needle and no pollution of the semiconductor chips is caused in the case ultraviolet rays at wavelength of 365 nm as the light are radiated at a radiation intensity within a prescribed range while satisfying relationships of the radiation intensity and the radiation time.

In the method for manufacturing the semiconductor chip of the invention, in the above-mentioned separation step, it is preferable to radiate ultraviolet rays in a manner that the radiation intensity X (mW/cm²; X is in a range from 500 to 10,000 mW/cm²) at wavelength of 365 nm and the radiation time Y (second) satisfy the relationships represented by the following formulas (1) and (2).
Y≦−1.90Ln(X)+16.55 (1)
Y≧−0.16Ln(X)+1.36 (2)

In the case ultraviolet rays having radiation intensity of 500 to 10,000 mW/cm² at wavelength of 365 nm are radiated while satisfying the relationships represented by the above-mentioned formula (2), since a large quantity of the gas is generated within a short time, the semiconductor chips can spontaneously be separated from the pressure sensitive adhesive layer and the separated semiconductor chips are thus kept as if they float on the pressure sensitive adhesive layer. In the case of such self separation, it is made possible to pick up the semiconductor chips easily by the needle-less pickup method using no needle and accordingly, the semiconductor chips are prevented from damages due to the impacts at the time of pickup or occurrence of cracks can be prevented.

On the other hand, in the case ultraviolet rays of a radiation intensity in a range from 500 to 10,000 mW/cm² at wavelength of 365 nm are radiated while satisfying the relationship represented by the above-mentioned formula (1), no oily decomposition product derived from the components contained in the pressure sensitive adhesive layer is generated and thus the semiconductor chips are not polluted.

Accordingly, within the range of satisfying the relationships represented by the above-mentioned formulas (1) and (2), it is made reliably possible both to easily pick up the semiconductor chips by the needle-less pickup method using no needle and to cause no pollution of the semiconductor chips with the oily decomposition products.

If the above-mentioned formula (2) is not satisfied because of low radiation intensity or short radiation time, it is sometimes impossible to reliably pick up the semiconductor chips and if the above-mentioned formula (1) is not satisfied because of high radiation intensity or long radiation time, the semiconductor chips may possibly be polluted.

In the case light is radiated immediately before the semiconductor chips are aspirated by an aspiration means or under the condition that the semiconductor chips are aspirated by an aspiration means, since a constant separation power is applied even at the time of gas generation from the pressure sensitive adhesive tape for dicing, the semiconductor chips and the pressure sensitive adhesive tape for dicing can be prevented from irregular separation and formation of un-separated parts and as a result the semiconductor chips can be picked up by the needle-less pickup method using no needle.

Further, to improve the production speed, it is required to increase the pickup speed. For example, it is possible to overlap the time to be taken for radiating light immediately before the semiconductor chips are aspirated by a suck pad and the time to be taken for pickup, and thus the productivity is improved. In this case, if it takes long from the time of light radiation to the time of aspiration of the semiconductor chips by using an aspiration means, irregular separation takes place to leave un-separated parts and therefore, it is preferable to radiate light within 1.0 second before aspiration.

A method of setting the starting and finishing of the light radiation and the radiation time is not particularly limited, and for example, in the case of a method of turning ON/OFF of a power source of a light (UV) radiation apparatus main body, it takes time to stabilize the lamp radiation intensity and therefore, it is preferable to install a shutting mechanism in the light radiation apparatus. Installation of the shutting mechanism in the light radiation apparatus makes it possible to stably control the starting and finishing of the light radiation and the radiation time.

In the separation step, light may be radiated at once to all of a plurality of divided semiconductor chips, however light radiation is preferably carried out successively to each semiconductor chip to separate each semiconductor chip. If light is radiated collectively, all of the semiconductor chips are at least partially self-separated, so that moving the semiconductor chips altogether to pick up each chip successively, each chip is separated at random to result in failure of the pickup and the productivity may rather be decreased.

The productivity decrease owing to the pickup failure can be suppressed by successively carrying out light radiation, separation, and pickup for each semiconductor chip.

In this case, it is preferable to radiate light, adjusting the radiation surface area so as to radiate to the entire surface of each semiconductor chip to the extent that no light is radiated to the neighboring semiconductor chips. That is, light is radiated to the inner side than the outer frame of the groove formed by the dicing.

A method of radiating light successively to each semiconductor chip for separation is particularly limited and for example, it is preferable that light emitted from a light source is led to the pressure sensitive adhesive tape for dicing stuck to the each semiconductor chip. A method of leading light may include the above-mentioned method of employing the converged light or a method of using a single or a plurality of bundles of optical fibers.

However, even if such a light leading means is employed, since the each semiconductor chip is parted from one another by the extremely thin groove with a width about several to several ten μm by dicing, it is difficult to radiate ultraviolet rays only to an aimed semiconductor chip but not to expose neighboring semiconductor chips to the ultraviolet rays at all by a presently available technique. Accordingly, before the ultraviolet rays are radiated to the aimed semiconductor chip, the semiconductor chips is to be exposed to the ultraviolet rays to a certain extent when the ultraviolet rays are radiated to other semiconductor chips. Depending on the surface area of the portion exposed previously, even if the ultraviolet rays are radiated to the aimed semiconductor chip in the separation step, reliable separation cannot be carried out in some cases.

The inventors of the invention have made investigations and have found that each semiconductor chip and the pressure sensitive adhesive tape for dicing can reliably be separated from each other in the case radiation intensity X (mW/cm²) of the ultraviolet rays radiated to an aimed semiconductor chip and a ratio Y₃ (%) of the surface area of the aimed semiconductor chip exposed previously to an ultraviolet ray when the ultraviolet rays being radiated to another semiconductor chip satisfy the relationship represented by the following formula (3) and that each semiconductor chip can be picked up reliably by the needle-less pickup method in the pickup step, which will be described later.
Y₃≦0.013X+46.5 (3)

(Y₃≦95)

In the case the ultraviolet rays having radiation intensity of 500 to 10,000 mW/cm² at wavelength of 365 nm are radiated in a manner that the relationship represented by the above-mentioned formula (3) is satisfied, each semiconductor chip and the pressure sensitive adhesive tape for dicing can reliably and spontaneously be separated and the separated semiconductor chip can be separated by self-separation as if floating in the pressure sensitive adhesive layer of the pressure sensitive adhesive tape for dicing. In the case of self-separation in such a manner, the semiconductor chips can be picked up by the needle-less pickup method using no needle and damages or cracks of the semiconductor chips due to the impact at the time of pickup can be prevented. In the case the relationship represented by the above-mentioned formula (3) is not satisfied, such self-separation cannot be accomplished in some cases.

If the ratio Y₃ (%) of the surface area of an aimed semiconductor chip exposed previously to the ultraviolet rays when the ultraviolet rays are radiated to other semiconductor chips is more than 95%, the aimed semiconductor chip is separated before the ultraviolet rays are radiated to the semiconductor chip and therefore, the semiconductor chip moves in the pickup step and it may result in impossibility of reliable pickup.

In the case light is radiated to each semiconductor chip, it is preferable to select the radiation manner in accordance with the manner of the separation step.

In the case the light radiated to the entire face of the semiconductor chip has radiation intensity having a fluctuation range within 20% of the average radiation intensity, the gas is generated evenly and the gas generation is effective particularly for self separation. Further, in the case of aiming self separation, it is also preferable to have the average radiation intensity in the inner portion of 5 to 30% of the adhesive face widened concentrically or rectangularly from the center position of the semiconductor chip in the entire adhesion surface area of the semiconductor chip being 40 to 70% of the intensity to the average value of the radiation intensity in the portion other than the inner portion of the adhesive face. In such a manner, the radiation intensity in the inner portion of the adhesive face of the semiconductor chips is made higher, so that the gas can be generated previously in the center part and the peripheral part is previously separated and gas leakage occurs from the peripheral part to prevent occurrence of separation failure.

In the case the light radiated to the semiconductor chip has the average radiation intensity in the inner portion of 5 to 30% of the adhesive face widened concentrically or rectangularly from the center position of the semiconductor chip in the entire adhesion surface area of the semiconductor chip being 150 to 250% of the intensity to the average value of the radiation intensity in the portion other than the inner portion of the adhesive face, the gas generation from the center part of the semiconductor chips is delayed, so that positioning difference of the semiconductor chip can be prevented at the time of separation.

The above-mentioned separation step may be carried out in an inert gas atmosphere such as nitrogen, argon, or helium. Execution of separation in the inert gas atmosphere, curing inhibition of the pressure sensitive adhesive composing the above-mentioned pressure sensitive adhesive layer by oxygen can be suppressed and particularly it is effective for separation of very small chips which have a high surface area ratio susceptive to the oxygen inhibition in the chip surface area.

In the above-mentioned separation step, it is preferable to control the temperature so as to adjust the temperature of the pressure sensitive adhesive tape for dicing to be 50° C. or lower at the time of gas generation by light radiation. If the temperature of the pressure sensitive adhesive tape for dicing is more than 50° C., the softness of the pressure sensitive adhesive tape for dicing is increased and the adhesion with the semiconductor chips is increased and therefore, it may possibly become difficult to separate them. In this connection, the cause of the temperature increase of the pressure sensitive adhesive tape for dicing at the time of separation is supposed to be heat beam contained in the light in the case light with high radiation intensity is radiated. Examples of a method of avoiding the temperature increase of the pressure sensitive adhesive tape for dicing may include a method of removing the heat beam to be radiated to the pressure sensitive adhesive tape for dicing by using a filter which cuts the heat beams and a method of cooling the pressure sensitive adhesive tape for dicing by blowing air from the outside.

The method for manufacturing the semiconductor chip of the invention comprises the pickup method for picking up the semiconductor chips by the needle-less pickup method. The needle-less pickup method is a pickup method using no needle and the needle-less pickup method can safely pick up semiconductor chips with no impact on the chips. The needle-less pickup method can also remarkably improve the productivity since semiconductor chips are not damaged even if the pickup speed is increased.

In the above-mentioned separation step, if the ultraviolet rays having radiation intensity of 500 mW/cm² or higher at wavelength of 365 nm are radiated, since the semiconductor chips are self-separated from the pressure sensitive adhesive tape, the semiconductor chips can easily be picked up only by aspirating them by an aspiration means such as an aspiration pad and the like without pushing up with a needle unlike a conventional method.

Further, in the above-mentioned separation step, if the light is radiated when the semiconductor chips are aspirated by using an aspiration means are radiated with light, which can be transferred to the pickup step, and the semiconductor chips can easily be picked up only by aspirating them by an aspiration means such as an aspiration pad and the like without pushing up with a needle unlike a conventional method.

In the pickup step, the pressure sensitive adhesive tape may be expanded or may not be expanded based on the necessary. For example, in the case the intervals between respectively neighboring semiconductor chips are very narrow or there is no interval, the intervals among respective semiconductor chips are widened by expansion and each semiconductor chip can easily be picked up without touching the neighboring semiconductor chips. On the other hand, if there are sufficient intervals among the semiconductor chips after dicing, each semiconductor chip can easily be picked up without touching neighboring semiconductor chips without expansion.

The method for manufacturing the semiconductor chip of the invention is capable of accurately carrying out dicing without causing positioning difference and picking up the diced semiconductor chips by the needle-less pickup method without pushing up the semiconductor chips by a needle unlike a conventional method, so that the semiconductor chips can safely be picked up without being applying impact. Further, since the semiconductor chips are not damaged even if the pickup speed is increased, the productivity can remarkably be improved. Further, in the case of manufacturing the semiconductor chips in which circuits particularly susceptive to damages are formed, the pressure sensitive adhesive tape may be stuck to the face where the circuits are formed and wafer backside dicing may be carried out to obtain the semiconductor chips without damaging the circuits.

The method for manufacturing the semiconductor chip of the invention comprises the tape adhesion step, the dicing step, the separation step, and the pickup step as indispensable steps and in the recent methods of manufacturing the semiconductor chips which have been complicated and sectionalized, a series of these steps are not necessarily carried out collectively in a single site and it may be possible that semiconductor wafers or semiconductor chips are transported or stored while being stuck to a pressure sensitive adhesive tape. Even in such a case, it is important that the pressure sensitive adhesive tape can be separated without damaging or polluting the semiconductor wafers and the semiconductor chips.

A method for separating a pressure sensitive adhesive tape in such a manner may includes a method for separating a pressure sensitive adhesive tape having a pressure sensitive adhesive layer containing a gas generating agent for generating a gas by radiating light from semiconductor wafers or semiconductor chips with the pressure sensitive adhesive tape stuck by radiating ultraviolet rays satisfying the relationships represented by the following formulas (1) and (2) between the radiation intensity X (mW/cm²; X is in a range from 500 to 10,000 mW/cm²) at wavelength of 365 nm and the radiation time Y (second), and a method separating a pressure sensitive adhesive tape having a pressure sensitive adhesive layer containing a gas generating agent for generating a gas by radiating light from a semiconductor wafer or a semiconductor chip with the pressure sensitive adhesive tape stuck, wherein radiation intensity X (mW/cm²; X is within 500 to 10,000 mW/cm²) of an ultraviolet ray with wavelength of 365 nm radiated to a semiconductor wafer or a semiconductor chip stuck to the pressure sensitive adhesive tape and a ratio Y₃ (%) of the surface area of the semiconductor chip exposed to an ultraviolet ray before the ultraviolet ray being radiated satisfy the relationship represented by the following formula (3). These separation methods of the pressure sensitive adhesive tapes also constitute the invention.
Y≦−1.90Ln(X)+16.55 (1)
Y≧−0.16Ln(X)+1.36 (2)
Y₃≦0.013X+46.5 (3)

(Y₃≦95)

A pressure sensitive adhesive tape for a method for separating a pressure sensitive adhesive tape of the invention can be the same pressure sensitive adhesive tape for dicing to be used in the method for manufacturing the semiconductor chip of the invention and the detail of operation of the method is also the same in the case of the method for manufacturing the semiconductor chip of the invention. According to the method for separating pressure sensitive adhesive tape, the stuck pressure sensitive adhesive tape can be separated without damaging or polluting the semiconductor wafers or the semiconductor chips.

### Effect of the Invention

The invention can provide a method for manufacturing a semiconductor chip capable of obtaining semiconductor chips at a high efficiency without damages.

### BEST MODE FOR CARRYING OUT THE INVENTION

Hereinafter, the invention will be described in more detail by way of the following examples, however it is not intended that the invention be limited to these examples.

### Example 1

### Preparation of Pressure Sensitive Adhesive

The following compounds were dissolved in ethyl acetate and polymerized by radiating ultraviolet rays to obtain an acrylic copolymer with a weight average molecular weight of 700,000.

Further, 3.5 parts by weight of 2-isocyanatoethyl methacrylate was added to 100 parts by weight on the basis of the resin solid matter of the ethyl acetate solution containing the obtained acrylic copolymer to carry out reaction and further 40 parts by weight of U324A (manufactured by Shin-Nakamura Chemical Co., Ltd.), 5 parts by weight of a photopolymerization initiator (Irgacure 651), and 0.5 parts by weight of polyisocyanate were mixed to 100 parts by weight on the basis of the resin solid matter of the ethyl acetate solution after the reaction to obtain an ethyl acetate solution of a pressure sensitive adhesive (1).

| | | |
|---|---|---|
| Butyl acrylate | 79 | parts by weight |
| Ethyl acrylate | 15 | parts by weight |
| Acrylic acid | 1 | part by weight |
| 2-hydroxyethyl acrylate | 5 | parts by weight |
| Photopolymerization initiator | 0.2 | parts by weight |
| (Irgacure 651, 50% ethyl acetate solution) | | |
| Lauryl mercaptan | 0.01 | parts by weight |

Also, a pressure sensitive adhesive (2) containing a gas generating agent was prepared by mixing 30 parts by weight of 2,2′-azobis-(N-butyl-2-methylpropionamide) and 3.6 parts by weight of 2,4-diethylthioxanthone to 100 parts by weight on the basis of resin solid matter of the ethyl acetate solution of the pressure sensitive adhesive (1).

(Manufacturing of Pressure Sensitive Adhesive Tape for Dicing)

The ethyl acetate solution of the pressure sensitive adhesive (2) was applied to a 75 μm-thick transparent polyethylene terephthalate (PET) film subjected to corona treatment in one face to form a coating with about 15 μm thickness in dry state by a doctor knife and heated at 110° C. for 5 minutes to dry the applied solution. The pressure sensitive adhesive layer after the drying showed an adhesion in dry state. Next, a PET film subjected to release treatment was stuck to the surface of the pressure sensitive adhesive (2) layer. After that, the resulting laminate film was kept still and aged at 40° C. for 3 days to obtain the pressure sensitive adhesive tape for dicing.

(Manufacturing of Semiconductor Chip)

The obtained pressure sensitive adhesive tape for dicing was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and high intensity ultraviolet rays having radiation intensity of 600 mW/cm² at wavelength of 365 nm were radiated to one of the chips for 1.0 second from the pressure sensitive adhesive tape side. For the ultraviolet ray radiation, a high intensity ultraviolet ray radiation apparatus (Spot Cure, manufactured by Ushio Inc.) for radiating spot-like high intensity ultraviolet rays from a tip end of an optical fiber was employed. By the ultraviolet ray radiation, the semiconductor chip was self-separated from the pressure sensitive adhesive tape for dicing.

Next, the semiconductor chip which was self-separated and floated on the pressure sensitive adhesive tape for dicing was aspirated and picked up by an aspiration pad.

The above-mentioned process was continuously carried out for 20 sheets of semiconductor chips to which the pressure sensitive adhesive tape for dicing was stuck at a speed of about 0.5 second per one semiconductor chip to investigate the success ratio of the pickup and the ratio of the semiconductor chips which were not at all damaged to the semiconductor chips whose pickup was successful. The results are shown in Table 1.

### Example 2

The manufacturing of the semiconductor chip was carried out in the same manner as Example 1, except that the high intensity ultraviolet rays having radiation intensity of 1000 mW/cm² at wavelength of 365 nm were radiated for 0.5 second.

The above-mentioned process was continuously carried out for 20 sheets of semiconductor chips to which the pressure sensitive adhesive tape for dicing was stuck at a speed of about 0.5 second per one semiconductor chip to investigate the success ratio of the pickup and the ratio of the semiconductor chips which were not at all damaged to the semiconductor chips whose pickup was successful. The results are shown in Table 1.

### Example 3

The pressure sensitive adhesive tape for dicing manufactured in Example 1 was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and high intensity ultraviolet rays having radiation intensity of 600 mW/cm² at wavelength of 365 nm were radiated to one of the chips for 1.0 second from the side of the pressure sensitive adhesive tape for dicing in the condition that the semiconductor chip was being aspirated by an aspiration pad. For the ultraviolet ray radiation, a high intensity ultraviolet ray radiation apparatus (Spot Cure, manufactured by Ushio Inc.) for radiating spot-like high intensity ultraviolet rays from a tip end of an optical fiber was employed. By the ultraviolet ray radiation, the semiconductor chip was self-separated from the pressure sensitive adhesive tape for dicing and could be picked up as it was.

The above-mentioned process was continuously carried out for 20 sheets of semiconductor chips to which the pressure sensitive adhesive tape for dicing was stuck at a speed of about 0.5 second per one semiconductor chip to investigate the success ratio of the pickup and the ratio of the semiconductor chips which were not at all damaged to the semiconductor chips whose pickup was successful. The results are shown in Table 1.

### Example 4

The pressure sensitive adhesive tape for dicing manufactured in Example 1 was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and 0.5 second before aspiration by an aspiration pad, high intensity ultraviolet rays were radiated from the side of the pressure sensitive adhesive tape for dicing. The radiation intensity of the ultraviolet rays was 600 mW/cm² at wavelength of 365 nm and the radiation time was 1.0 second. For the ultraviolet ray radiation, a high intensity ultraviolet ray radiation apparatus (Spot Cure, manufactured by Ushio Inc.) for radiating spot-like high intensity ultraviolet rays from a tip end of an optical fiber was employed. By the ultraviolet ray radiation, the semiconductor chip was self-separated from the pressure sensitive adhesive tape for dicing and could be picked up as it was.

The above-mentioned process was continuously carried out for 20 sheets of semiconductor chips to which the pressure sensitive adhesive tape for dicing was stuck at a speed of about 0.5 second per one semiconductor chip to investigate the success ratio of the pickup and the ratio of the semiconductor chips which were not at all damaged to the semiconductor chips whose pickup was successful. The results are shown in Table 1.

### Comparative Example 1

A pressure sensitive adhesive tape for dicing having a pressure sensitive adhesive layer containing a photocurable type pressure sensitive adhesive (ELEPHOLDER UE-110BJ manufactured by Nitto Denko Corp.) was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and ultraviolet rays of 100 mW intensity were radiated for 5 seconds to one of the chips from the side of the pressure sensitive adhesive tape for dicing.

The semiconductor chip was not self-separated by the ultraviolet ray radiation and was not picked up by aspiration with an aspiration pad, so that after the ultraviolet ray radiation, the semiconductor chip was picked up by a pickup method using a needle.

The above-mentioned process was continuously carried out for 20 sheets of semiconductor chips to which the pressure sensitive adhesive tape for dicing was stuck at a speed of about 1.0 second per one semiconductor chip at which the semiconductor chips were hardly damaged to investigate the success ratio of the pickup and the ratio of the semiconductor chips which were not at all damaged to the semiconductor chips whose pickup was successful. The results are shown in Table 1.

### Comparative Example 2

The pressure sensitive adhesive tape for dicing obtained in Example 1 was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and high intensity ultraviolet rays having radiation intensity of 300 mW/cm² at wavelength of 365 nm were radiated for 1.0 second to one of the semiconductor chips from the side of the pressure sensitive adhesive tape for dicing. The semiconductor chip was not self-separated by the ultraviolet ray radiation and was not picked up by aspiration with an aspiration pad, so that after the ultraviolet ray radiation, the semiconductor chip was picked up by a pickup method using a needle.

The above-mentioned process was continuously carried out for 20 sheets of semiconductor chips to which the pressure sensitive adhesive tape for dicing was stuck at a speed of about 1.0 second per one semiconductor chip at which the semiconductor chips were hardly damaged to investigate the success ratio of the pickup and the ratio of the semiconductor chips which were not at all damaged to the semiconductor chips whose pickup was successful. The results are shown in Table 1.

### Comparative Example 3

The pressure sensitive adhesive tape for dicing obtained in Example 1 was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and high intensity ultraviolet rays having radiation intensity of 600 mW/cm² at wavelength of 365 nm were radiated to one of the semiconductor chips in a region of a diameter of 3 mm from the center part from the side of the pressure sensitive adhesive tape for dicing and simultaneously ultraviolet rays having radiation intensity of 100 mW/cm² were radiated to the peripheral part for 1.0 second, respectively.

The peripheral part other than the center part was not self-separated by the ultraviolet ray radiation and the semiconductor chip was difficult to be picked up by aspiration with an aspiration pad, so that after the ultraviolet ray radiation, the semiconductor chip was picked up by a pickup method using a needle.

The above-mentioned process was continuously carried out for 20 sheets of semiconductor chips to which the pressure sensitive adhesive tape for dicing was stuck at a speed of about 1.0 second per one semiconductor chip at which the semiconductor chips were hardly damaged to investigate the success ratio of the pickup and the ratio of the semiconductor chips which were not at all damaged to the semiconductor chips whose pickup was successful. The results are shown in Table 1.

### Comparative Example 4

The pressure sensitive adhesive tape for dicing obtained in Example 1 was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and high intensity ultraviolet rays having radiation intensity of 100 mW/cm² at wavelength of 365 nm were radiated to one of the semiconductor chips in a region of a diameter of 3 mm from the center part from the side of the pressure sensitive adhesive tape for dicing and simultaneously ultraviolet rays having radiation intensity of 600 mW/cm² were radiated to the peripheral part for 1.0 second, respectively.

The center part was not self-separated by the ultraviolet ray radiation and the semiconductor chip was difficult to be picked up by aspiration with an aspiration pad, so that the semiconductor chip was picked up by a pickup method using a needle.

The above-mentioned process was continuously carried out for 20 sheets of semiconductor chips to which the pressure sensitive adhesive tape for dicing was stuck at a speed of about 1.0 second per one semiconductor chip at which the semiconductor chips were hardly damaged to investigate the success ratio of the pickup and the ratio of the semiconductor chips which were not at all damaged to the semiconductor chips whose pickup was successful. The results are shown in Table 1.

TABLE 1

| | Time taken for the | | Ratio of the |
|---|---|---|---|
| | pickup per one | | semiconductor |
| | semiconductor | Success ratio of | chips without |
| | chip (second) | the pickup (%) | damages (%) |
| Example 1 | 0.5 | 75 | 87 |
| Example 2 | 0.5 | 85 | 88 |
| Example 3 | 0.5 | 90 | 88 |
| Example 4 | 0.5 | 90 | 88 |
| Comparative | 1.0 | 10 | 50 |
| Example 1 | | | |
| Comparative | 1.0 | 30 | 67 |
| Example 2 | | | |
| Comparative | 1.0 | 40 | 75 |
| Example 3 | | | |
| Comparative | 1.0 | 45 | 78 |
| Example 4 | | | |

### Example 5

The pressure sensitive adhesive tape for dicing obtained in Example 1 was stuck to a face with a circuit formed of a 50 μm-thick silicon wafer with the circuit formed at a normal temperature and a normal pressure. Next, the silicon wafer was diced (by a wafer backside dicing method) from the side where the circuit was not formed into 5 mm×5 mm to obtain semiconductor chips.

The obtained semiconductor chips to which the pressure sensitive adhesive tape for dicing was stuck were set while the semiconductor chip side was set to be the upper face and high intensity ultraviolet rays having radiation intensity of 600 mW/cm² at wavelength of 365 nm were radiated to one of the chips for 1.0 second. For the ultraviolet ray radiation, a high intensity ultraviolet ray radiation apparatus (Spot Cure, manufactured by Ushio Inc.) for radiating spot-like high intensity ultraviolet rays from a tip end of an optical fiber was employed. By the ultraviolet ray radiation, the semiconductor chip was self-separated from the pressure sensitive adhesive tape for dicing.

Next, the semiconductor chip self-separated and floated on the pressure sensitive adhesive tape for dicing was aspirated and picked up by an aspiration pad.

The above-mentioned process was continuously carried out for 20 sheets of semiconductor chips and the circuit of each obtained semiconductor chip was observed by a microscope to find no damage on the circuit of any semiconductor chips.

### Comparative Example 5

A pressure sensitive adhesive tape for dicing having a pressure sensitive adhesive layer containing a photocurable type adhesive (ELEPHOLDER UE-110BJ manufactured by Nitto Denko Corp.) was stuck to a face with a circuit formed of a 50 μm-thick silicon wafer with the circuit formed at a normal temperature and a normal pressure. Next, the silicon wafer was diced (by a wafer backside dicing method) from the side where no circuit was formed into 5 mm×5 mm to obtain semiconductor chips.

The obtained semiconductor chips to which the pressure sensitive adhesive tape for dicing was stuck were set while the semiconductor chip side was set to be the upper face and ultraviolet rays of 100 mW intensity were radiated for 5 seconds to one of the chip from the side of the pressure sensitive adhesive tape for dicing.

The semiconductor chip was not self-separated by the ultraviolet ray radiation and was not picked up by aspiration with an aspiration pad, so that after the ultraviolet ray radiation, the semiconductor chip was picked up by a pickup method using a needle.

The above-mentioned process was continuously carried out for 20 sheets of semiconductor chips and the circuit of each of the obtained semiconductor chips was observed by a microscope to find that every circuit of the semiconductor chip had damage supposedly formed at the time of pushing up the semiconductor chip, using the needle.

### Test Example 1

The pressure sensitive adhesive tape for dicing obtained in Example 1 was stuck to a face with no circuit of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and ultraviolet rays having radiation intensity and radiation time combined as shown in Table 1 were radiated to one of them for 1.0 second from the side of the pressure sensitive adhesive tape for dicing. For the ultraviolet ray radiation, a high intensity ultraviolet ray radiation apparatus (Spot Cure, manufactured by Ushio Inc.) for radiating spot-like high intensity ultraviolet rays from a tip end of an optical fiber was employed.

In the method for manufacturing the semiconductor chip as described above, the pickup property by a needle-less pickup method and the contamination of the obtained semiconductor chips were evaluated based on the following standards.

The results are shown in Table 2.

The data shown in Table 2 shows (the satisfaction of the formulas (1) and (2))/(the pickup property by the needle-less pickup method)/(contamination of the semiconductor chips).

(1) Pickup Property by the Needle-Less Pickup Method

The semiconductor chips on the pressure sensitive adhesive tape for dicing after the ultraviolet ray radiation were adsorbed and picked up by an aspiration pad. When the operation was successively carried out at a speed of about 0.5 second per one semiconductor chip for 10 sheets of the semiconductor chips to which the pressure sensitive adhesive tape for dicing was stuck, if the ratio of the semiconductor chips which were picked up successfully without being damaged was 70% or higher, the case was evaluated as ο and if the ratio was less than 70%, the case was evaluated as ×.

(2) Contamination of the Semiconductor Chips

The surface of the obtained semiconductor chips were observed by an optical microscope with a magnification of 200 times and evaluated and if no substance stuck to the surface was observed, the case was evaluated as ο and if a substance stuck to the surface was observed, the case was evaluated as x.

TABLE 2

| | | Ratio of the surface area exposed to ultraviolet rays (%) | | | | | | | | |
|---|---|---|---|---|---|---|---|---|---|---|
| | | 10 | 20 | 30 | 40 | 50 | 60 | 70 | 80 | 95 |
| Ultra- | 500 | 10 | 10 | 10 | 10 | 9 | 2 | 1 | 1 | 0 |
| violet | | | | | | | | | | |
| rays | 1500 | 10 | 10 | 10 | 10 | 10 | 9 | 2 | 1 | 0 |
| radi- | | | | | | | | | | |
| ation | | | | | | | | | | |
| inten- | 2500 | 10 | 10 | 10 | 10 | 10 | 10 | 9 | 2 | 0 |
| sity | | | | | | | | | | |
| (mW/ | 3500 | 10 | 10 | 10 | 10 | 10 | 10 | 10 | 9 | 0 |
| cm²) | | | | | | | | | | |

### Test Example 2

The pressure sensitive adhesive tape for dicing obtained in Example 1 was stuck to a face with no circuit formed of a 50 μm-thick silicon wafer with a circuit formed at a normal temperature and a normal pressure. Next, the silicon wafer was diced into 5 mm×5 mm to obtain semiconductor chips.

The obtained semiconductor chips to which the pressure sensitive adhesive tape for dicing was stuck were set while the semiconductor chip side was set to be the upper face and ultraviolet rays were radiated to each semiconductor chip by a high intensity ultraviolet ray radiation apparatus (Spot Cure, manufactured by Ushio Inc.) for radiating spot-like high intensity ultraviolet rays from a tip end of an optical fiber.

In this case, the radiation was controlled in a manner that the ultraviolet ray intensity X (mW/cm²) radiated to an aimed semiconductor chip and the ratio Y (%) of the surface area of the aimed semiconductor chip exposed previously to ultraviolet rays when the ultraviolet rays were radiated to other semiconductor chips satisfied the combinations shown in Table 3.

In the method for manufacturing the semiconductor chip as described above, 10 semiconductor chips were picked up by the needle-less pickup method and the number of the semiconductor chips which were picked up without being damaged was counted.

The results are shown in Table 3.

TABLE 3

| | | Radiation intensity (mW/cm²) | | |
|---|---|---|---|---|
| | | 500 | 1000 | 3000 |
| Radi- | 0.05 | unsatisfied/X/◯ | unsatisfied/X/◯ | unsatisfied/X/◯ |
| ation | 0.1 | unsatisfied/X/◯ | unsatisfied/X/◯ | satisfied/◯/◯ |
| time | 0.15 | unsatisfied/X/◯ | unsatisfied/X/◯ | satisfied/◯/◯ |
| (sec- | 0.2 | unsatisfied/X/◯ | satisfied/◯/◯ | satisfied/◯/◯ |
| ond) | 0.3 | unsatisfied/X/◯ | satisfied/◯/◯ | satisfied/◯/◯ |
| | 0.4 | satisfied/◯/◯ | satisfied/◯/◯ | satisfied/◯/◯ |
| | 0.6 | satisfied/◯/◯ | satisfied/◯/◯ | satisfied/◯/◯ |
| | 0.8 | satisfied/◯/◯ | satisfied/◯/◯ | satisfied/◯/◯ |
| | 1.0 | satisfied/◯/◯ | satisfied/◯/◯ | satisfied/◯/◯ |
| | 1.5 | satisfied/◯/◯ | satisfied/◯/◯ | satisfied/◯/◯ |
| | 2.0 | satisfied/◯/◯ | satisfied/◯/◯ | unsatisfied/◯/X |
| | 3.0 | satisfied/◯/◯ | satisfied/◯/◯ | unsatisfied/◯/X |
| | 5.0 | satisfied/◯/◯ | unsatisfied/◯/X | unsatisfied/◯/X |
| | 6.0 | unsatisfied/◯/X | unsatisfied/◯/X | unsatisfied/◯/X |

The data shows (satisfaction of the formula)/(the pickup property)/(contamination of the semiconductor chips)

### INDUSTRIAL APPLICABILITY OF THE INVENTION

The invention can provide a method for manufacturing a semiconductor chip capable of obtaining a semiconductor chip at a high manufacturing efficiency without damages.

1. A method for manufacturing a semiconductor chip,
which comprises a tape adhesion step of sticking a pressure sensitive adhesive tape for dicing having a pressure sensitive adhesive layer containing a gas generating agent for generating a gas by radiating light to a semiconductor wafer with a circuit formed; a dicing step for dicing the wafer with the pressure sensitive adhesive tape for dicing stuck and dividing the semiconductor wafer into each semiconductor chip; a separation step of separating at least a portion of the pressure sensitive adhesive tape for dicing from the semiconductor chip by radiating light to the divided each semiconductor chip; and a pickup step of picking the semiconductor chip up by a needle-less pickup method.

2. The method for manufacturing a semiconductor chip according to claim 1,
wherein the pressure sensitive adhesive tape for dicing is stuck to the face with the circuit formed of the semiconductor wafer in the tape adhesion step.

3. The method for manufacturing a semiconductor chip according to claim 1,
wherein an ultraviolet ray having radiation intensity of 500 mW/cm² or higher at wavelength of 365 nm is radiated in the separation step.

4. The method for manufacturing a semiconductor chip according to claim 1,
wherein light is radiated immediately before the semiconductor chip is aspirated by an aspiration means or while the semiconductor chip is aspirated by an aspiration means in the separation step.

5. The method for manufacturing a semiconductor chip according to claim 1,
wherein light emitted from a light source is led to the pressure sensitive adhesive tape for dicing stuck to each semiconductor chip in the separation step.

6. The method for manufacturing a semiconductor chip according to claim 1,
wherein radiation intensity X (mW/cm²) of the ultraviolet ray radiated to an aimed semiconductor chip and a ratio Y₃ (%) of surface area of the aimed semiconductor chip exposed previously to an ultraviolet ray when the ultraviolet ray being radiated to another semiconductor chip satisfy the relationship represented by the following formula (3):
Y₃≦0.013X+46.5 (3)
(Y₃≦95).

7. The method for manufacturing a semiconductor chip according to claim 5,
wherein the light radiated to the entire face of the semiconductor chip has radiation intensity having a fluctuation range within 20% of the average radiation intensity.

8. The method for manufacturing a semiconductor chip according to claim 5,
wherein the light radiated to the semiconductor chip has the average radiation intensity in the inner portion of 5 to 30% of the adhesive face widened concentrically or rectangularly from the center position of the semiconductor chip in the entire adhesion surface area of the semiconductor chip being 40 to 70% of the intensity to the average value of the radiation intensity in the portion other than the inner portion of the adhesive face.

9. The method for manufacturing a semiconductor chip according to claim 5,
wherein the light radiated to the semiconductor chip has the average radiation intensity in the inner portion of 5 to 30% of the adhesive face widened concentrically or rectangularly from the center position of the semiconductor chip in the entire adhesion surface area of the semiconductor chip being 150 to 250% of the intensity to the average value of the radiation intensity in the portion other than the inner portion of the adhesive face.

10. The method for manufacturing a semiconductor chip according to claim 1,
wherein the separation step is carried out in inert gas atmosphere.

11. The method for manufacturing a semiconductor chip according to claim 1,
wherein the pickup is carried out without expanding the pressure sensitive adhesive tape for dicing in the pickup step.

12. A method for separating a pressure sensitive adhesive tape for separating a pressure sensitive adhesive tape having a pressure sensitive adhesive layer containing a gas generating agent for generating a gas by radiating light from a semiconductor wafer or a semiconductor chip with the pressure sensitive adhesive tape stuck,
wherein radiation intensity X (mW/cm²; X is within 500 to 10,000 mW/cm²) of an ultraviolet ray with wavelength of 365 nm radiated to a semiconductor wafer or a semiconductor chip stuck to the pressure sensitive adhesive tape and a ratio Y₃ (%) of the surface area of the semiconductor chip exposed to an ultraviolet ray before the ultraviolet ray being radiated satisfy the relationship represented by the following formula (3):
Y₃≦0.013X+46.5 (3)
(Y₃≦95).

13. The method for manufacturing a semiconductor chip according to claim 2,
wherein an ultraviolet ray having radiation intensity of 500 mW/cm² or higher at wavelength of 365 nm is radiated in the separation step.

14. The method for manufacturing a semiconductor chip according to claim 2,
wherein light is radiated immediately before the semiconductor chip is aspirated by an aspiration means or while the semiconductor chip is aspirated by an aspiration means in the separation step.

15. The method for manufacturing a semiconductor chip according to claim 2,
wherein light emitted from a light source is led to the pressure sensitive adhesive tape for dicing stuck to each semiconductor chip in the separation step.

16. The method for manufacturing a semiconductor chip according to claim 2, wherein radiation intensity X (mW/cm²) of the ultraviolet ray radiated to an aimed semiconductor chip and a ratio Y₃ (%) of surface area of the aimed semiconductor chip exposed previously to an ultraviolet ray when the ultraviolet ray being radiated to another semiconductor chip satisfy the relationship represented by the following formula (3):
Y₃≦0.013X+46.5 (3)
(Y₃≦95).

17. The method for manufacturing a semiconductor chip according to claim 6,
wherein the light radiated to the entire face of the semiconductor chip has radiation intensity having a fluctuation range within 20% of the average radiation intensity.

18. The method for manufacturing a semiconductor chip according to claim 6,
wherein the light radiated to the semiconductor chip has the average radiation intensity in the inner portion of 5 to 30% of the adhesive face widened concentrically or rectangularly from the center position of the semiconductor chip in the entire adhesion surface area of the semiconductor chip being 40 to 70% of the intensity to the average value of the radiation intensity in the portion other than the inner portion of the adhesive face.

19. The method for manufacturing a semiconductor chip according to claim 6,
wherein the light radiated to the semiconductor chip has the average radiation intensity in the inner portion of 5 to 30% of the adhesive face widened concentrically or rectangularly from the center position of the semiconductor chip in the entire adhesion surface area of the semiconductor chip being 150 to 250% of the intensity to the average value of the radiation intensity in the portion other than the inner portion of the adhesive face.

20. The method for manufacturing a semiconductor chip according to claim 2,
wherein the separation step is carried out in inert gas atmosphere.

21. The method for manufacturing a semiconductor chip according to claim 2,
wherein the pickup is carried out without expanding the pressure sensitive adhesive tape for dicing in the pickup step.
